(19) United States
(12) Patent Application Publication
(10) Pub. No.: US 2010/0038778 A1
(43) Pub. Date: Feb. 18, 2010

(54) INTEGRATED CIRCUIT STRUCTURES AND FABRICATING METHODS THAT USE VOIDS IN THROUGH HOLES AS JOINING INTERFACES

(75) Inventors: Kwang-Yong Lee, Gyeonggi-do (KR); Sun-Won Kang, Seoul (KR); Sang-Hee Kim, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/402,123

(22) Filed: Mar. 11, 2009

(30) Foreign Application Priority Data
Aug. 13, 2008 (KR) 10-2008-079444

(51) Int. Cl. H01L 23/50; H01L 21/441

(52) U.S. Cl. 257/737; 438/597; 257/E23.079; 257/E21.477

(57) ABSTRACT

A void that is created in a conductive electrode in a through hole that extends through an integrated circuit substrate can be used as a joining interface. For example, an integrated circuit structure includes an integrated circuit substrate having a conductive pad on a first face thereof, and a through hole that extends through the integrated circuit substrate from a second face of the integrated circuit substrate that is opposite to the first face and through the pad. A conductive electrode is provided in the through hole that extends from the second face to the first face through and onto the pad. The conductive electrode includes a void therein adjacent the second face. The void includes a void opening adjacent the second face that defines inner walls of the conductive electrode. A conductive material is provided in the void that directly contacts the inner walls of the conductive electrode. Related fabrication methods are also disclosed.

### CROSS-REFERENCE TO RELATED APPLICATION

This application claims priority under 35 USC §119 to Korean Patent Application No. 10-2008-079444, filed on Aug. 13, 2008, the disclosure of which is hereby incorporated herein by reference in its entirety as if set forth fully herein.

### BACKGROUND OF THE INVENTION

Integrated circuit structures are widely used for consumer, commercial and other applications. As is well known, an integrated circuit structure may include an integrated circuit substrate (also referred to as a “chip”), which may itself include a semiconductor layer having one or more insulating and/or conductive layers thereon, and one or more conductive pads on a face thereof.

The integration density of devices in integrated circuit structures continues to increase, so that more active and/or passive devices can be provided in a given integrated circuit structure. Moreover, packaging of integrated circuit structures continues to evolve, so as to provide increasing packaging density. In particular, three-dimensional integrated circuit structures have been provided by stacking a plurality of integrated circuit substrates, to provide a Wafer Stack Package (WSP).

In providing a WSP, a conductive via is often used that extends through a given integrated circuit substrate and that may also extend through a plurality of stacked integrated circuit substrates. These conductive vias may be used to provide interconnections among the stacked integrated circuit substrates. These conductive vias may be referred to as Through Silicon Via (TSV) or Through Wafer Via (TWV) technology.

Unfortunately, the aspect ratio of the through hole that extends through one or more integrated circuit substrates may be very high. In filling this through hole with a conductive material, a void may be generated. The void may adversely impact the reliability of the stacked package.

### SUMMARY OF THE INVENTION

Various embodiments of the present invention can advantageously use a void that is created in a conductive electrode in a through hole that extends through an integrated circuit substrate, as a joining interface. For example, an integrated circuit structure according to some embodiments includes an integrated circuit substrate having a conductive pad on a first face thereof, and a through hole that extends through the integrated circuit substrate from a second face of the integrated circuit substrate that is opposite to the first face and through the pad. A conductive electrode is provided in the through hole that extends from the second face to the first face through and onto the pad. The conductive electrode includes a void therein adjacent the second face. The void includes a void opening adjacent the second face that defines inner walls of the conductive electrode.

In some embodiments, the void is a tapered void that tapers from the void opening and the inner walls are tapered inner walls. In other embodiments, the tapered void also defines a void width that decreases from the second face toward the first face. In yet other embodiments, the through hole itself is a tapered through hole. In still other embodiments. a conductive bump is provided on the conductive electrode adjacent the pad. In yet other embodiments, a conductive material is provided in the void that directly contacts the inner walls of the conductive electrode. In still other embodiments, the conductive material also protrudes outside the void, beyond the substrate. Yet other embodiments provide a redistribution line on the first face that electrically contacts and extends away from the pad, and further provide a conductive bump on the redistribution line, offset from the pad.

In still other embodiments, a second substrate is provided on the second face and a conductive bump is provided on the second substrate that extends into the void and directly contacts the inner walls of the conductive electrode. In yet other embodiments, a second integrated circuit substrate is provided having a second conductive pad on a first face thereof and a second through hole that extends through the second integrated circuit substrate from the second face of the second integrated circuit substrate that is opposite the first face, to the first face and through the second pad. A second conductive electrode is provided in the second through hole that extends from the second face to the first face of the second integrated circuit substrate and through and onto the second pad. The second conductive electrode includes a second void therein adjacent the second face. The second void has a void opening adjacent the second face that defines second inner walls of the second conductive electrode. In these embodiments, the conductive bump extends from the second conductive electrode adjacent the second pad into the first void, and directly contacts the first inner wall of the first conductive electrode. In still other embodiments, a third substrate is provided on the second face of the second integrated circuit substrate, and second conductive bump is provided on the third substrate that extends into the second void and directly contacts the second inner walls of the second conductive electrode. A molding layer may also be provided that extends from the second substrate and that covers the first and, in some embodiments the first and second, integrated circuit substrates. In still other embodiments, the conductive bump extends from the second conductive electrode adjacent the second pad, to directly contact the first conductive electrode into the first void.

Integrated circuit structures according to various embodiments may be packaged to provide various devices. In some embodiments, the integrated circuit substrate comprises an integrated circuit memory device substrate. A processor and an input/output system are connected to the integrated circuit memory device substrate via the conductive electrode, to provide an electronic system. The electronic system may comprise a mobile phone, media player, navigation system and/or a computer. In other embodiments, a memory controller may be connected to the integrated circuit memory device substrate via the conductive electrode to provide a memory card.

Integrated circuits may be fabricated according to various embodiments by forming a through hole in an integrated circuit substrate having a conductive pad on a first face thereof. The through hole extends through the integrated circuit substrate from a second face of the integrated circuit substrate that is opposite the first face, to the first face and through the pad. A conductive electrode is formed in the through hole that extends from the second face to the first face and through and onto the pad. The conductive electrode includes a void therein adjacent the second face. The void includes a void opening adjacent the second face that defines inner walls of the conductive electrode.

In some embodiments, a conductive bump is formed on the conductive electrode adjacent the pad. In other embodiments, a conductive material is pushed into the void to directly contact the inner walls of the conductive electrode. In some embodiments, the conductive material also protrudes outside the void, beyond the substrate. In still other embodiments, the pushing is performed at an elevated temperature, so as to increase plasticity of the conductive material as it is pushed into the void. In still other embodiments, a conductive material is reflowed into the void to directly contact the inner walls of the conductive electrode. In yet other embodiments, a conductive bump is formed on a redistribution line on the first face that electrically contacts and extends away from the pad. In still other embodiments, the conductive bump that is pushed into the void is itself on a second substrate. In yet other embodiments, a molding layer is formed on the second substrate that covers the integrated circuit substrate.

A through hole itself may be formed, according to various embodiments, by forming a blind hole in an integrated circuit substrate, that extends only partially through the integrated circuit substrate from a first face thereof partially to a second face thereof. A conductive electrode is formed in the blind hole, such that the conductive electrode fills the blind hole adjacent the first face, and produces a void therein adjacent the second face. At least some of the substrate is then removed from the second face, to expose the void. These through hole forming methods may be used with any of the embodiments described herein and may also be used independent of any of the embodiments described herein.

### BRIEF DESCRIPTION OF THE DRAWINGS

FIGS. 1A, 1B, 2, 3, 4A, 4B, 5, 6, 7, 8 and 9 are cross-sectional views of integrated circuit structures according to various embodiments.

FIG. 10 is a block diagram of a card that can include integrated circuit structures according to various embodiments.

FIG. 11 is a block diagram of an electronic system that can include integrated circuit structures according to various embodiments.

FIGS. 12-16 are cross-sectional views illustrating methods of fabricating integrated circuit structures according to various embodiments and integrated circuit structures so fabricated according to various embodiments.

FIGS. 17-19 are cross-sectional views illustrating methods of fabricating integrated circuit structures according to other embodiments and integrated circuit structures so fabricated according to other embodiments.

FIG. 20 is a cross-sectional view illustrating methods of fabricating integrated circuit structures according to still other embodiments and integrated circuit structures so fabricated according to still other embodiments.

FIG. 21 is a cross-sectional view illustrating methods of fabricating integrated circuit structures according to yet other embodiments and integrated circuit structures so fabricated according to yet other embodiments.

FIGS. 22-23 are cross-sectional views illustrating methods of fabricating integrated circuit structures according to other embodiments and integrated circuit structures so fabricated according to other embodiments.

FIGS. 24-25 are cross-sectional views illustrating methods of fabricating integrated circuit structures according to yet other embodiments and integrated circuit structures so fabricated according to yet other embodiments.

### DETAILED DESCRIPTION

The present invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions may be exaggerated for clarity. Like numbers refer to like elements throughout. As used herein the term “and/or” includes any and all combinations of one or more of the associated listed items and may be abbreviated as “/”.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “having,” “having,” “includes,” “including” and/or variations thereof, when used in this specification, specify the presence of stated features, regions, steps, operations, elements, and/or components, but do not preclude the presence or addition of one or more other features, regions, steps, operations, elements, components, and/or groups thereof.

It will be understood that when an element such as a layer or region is referred to as being “on” or extending “onto” another element (or variations thereof), it can be directly on or extend directly onto the other element or intervening elements may also be present. In contrast, when an element is referred to as being “directly on” or extending “directly onto” another element (or variations thereof), there are no intervening elements present. It will also be understood that when an element is referred to as being “connected” or “coupled” to another element (or variations thereof), it can be directly connected or coupled to the other element or intervening elements may be present. In contrast, when an element is referred to as being “directly connected” or “directly coupled” to another element (or variations thereof), there are no intervening elements present.

It will be understood that, although the terms first, second, etc. may be used herein to describe various elements, components, regions, layers and/or sections, these elements, materials, regions, layers and/or sections should not be limited by these terms. These terms are only used to distinguish one element, material, region, layer or section from another element, material, region, layer or section. Thus, a first element, material, region, layer or section discussed below could be termed a second element, material, region, layer or section without departing from the teachings of the present invention.

Relative terms, such as “lower”, “back”, and “upper” may be used herein to describe one element's relationship to another element as illustrated in the Figures. It will be understood that relative terms are intended to encompass different orientations of the device in addition to the orientation depicted in the Figures. For example, if the structure in the Figure is turned over, elements described as being on the “backside” of substrate would then be oriented on “upper” surface of the substrate. The exemplary term “upper”, can therefore, encompasses both an orientation of “lower” and “upper,” depending on the particular orientation of the figure. Similarly, if the structure in one of the figures is turned over, elements described as “below” or “beneath” other elements would then be oriented “above” the other elements. The exemplary terms “below” or “beneath” can, therefore, encompass both an orientation of above and below.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated, typically, may be rounded. Thus, the regions illustrated in the figures are schematic in nature and their shapes are not intended to illustrate the precise shape of a region and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

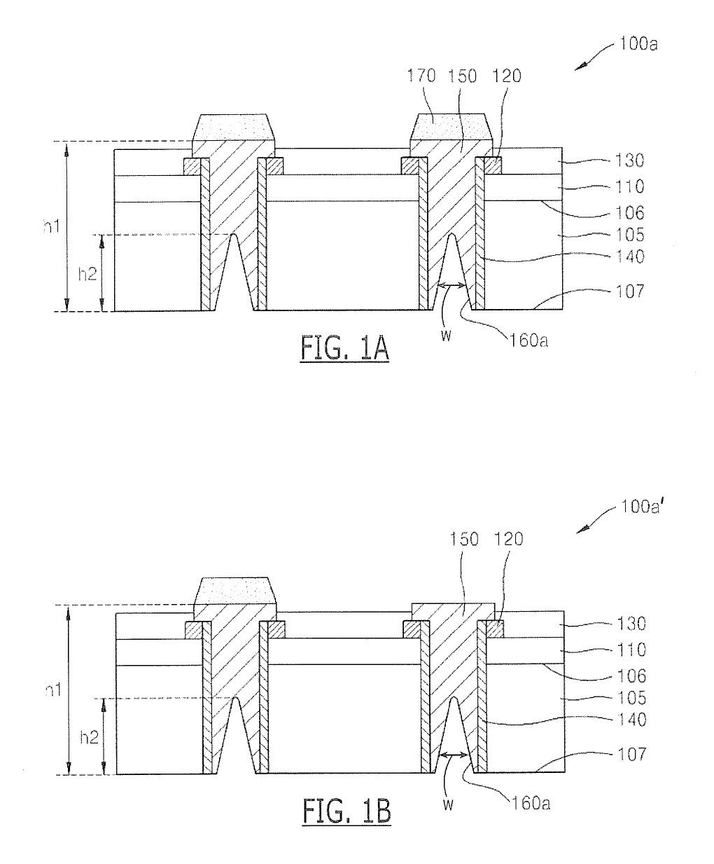

FIG. 1A is a cross-sectional view of an integrated circuit structure according to various embodiments. Referring to FIG. 1A, the integrated circuit structure 100a includes an integrated circuit substrate 105 having a first or top face 106 and a second or bottom face 107 that is opposite the first face 106. The second face 107 may be a thinned second face, as will be described below. The integrated circuit substrate 105 may include a single element and/or compound semiconductor substrate and/or any other single layer or multilayer microelectronic substrate. The integrated circuit substrate 105 may provide a memory device, a logic device and/or other conventional integrated circuit device. An interlayer dielectric layer 110 may be provided on the first face 106 and at least one conductive pad 120 may be provided on the first face 106. A passivation layer 130 also may be provided that exposes the conductive pad 120 on the interlayer dielectric layer 110. In other embodiments, a plurality of dielectric layers and/or conductive (wiring) layers may be provided, for example, on the first face 106 and/or the passivation layer 130. Additionally, a separate integrated circuit may be provided in the interlayer dielectric layer 110. Moreover, in still other embodiments, passive devices, such as capacitors, may also be provided on the substrate 105.

A through hole is provided that extends through the integrated circuit substrate 105 from the second face 107 of the integrated circuit substrate 105 to the first face 106 and through the pad 120. A conductive electrode 150, also referred to as a via electrode, is provided in the through hole that extends from the second face 107 to the first face 105 and through and onto the pad 120. The conductive electrode 150 includes a void 160a therein, including a void opening adjacent the second face 107 that defines inner walls of the conductive electrode 150. In some embodiments, as illustrated in FIG. 1A, the void 160a is a tapered void that tapers from the void opening, and the inner walls are tapered inner walls. Thus, in some embodiments, the tapered void also defines a void width w that decreases from the second face 107 toward the first face 106.

Accordingly, the conductive electrode 150 covers at least a portion of the top (exposed) surface of the conductive pad 120 and extends from the conductive pad 120 to the second surface 107, so that the conductive electrode 150 is exposed from the second surface 107. The conductive electrode 150 can deliver a signal from the integrated circuit structure 100a to beneath the second surface 107 by being connected with the top surface of the conductive pad 120.

As also shown in FIG. 1A, the void 160a may have a shape such that its width w gradually diminishes when proceeding from the second surface 107 to the first surface 106. The profile of the void 160a may vary, however, depending on the formation conditions of the conductive electrode 150 and the height and/or shape thereof. For example, the void may taper linearly, nonlinearly and/or in an abrupt (stepped) manner. In some embodiments, the height h2 of the void 160a may be two-thirds or less of the height h1 of the conductive electrode 150.

In some embodiments, a spacer layer 140 may be disposed between the conductive electrode 150 and the interlayer dielectric layer 110 and the substrate 105, to insulate the substrate 105 and/or the interlayer dielectric layer 110 from the conductive electrode 150. The spacer layer 140 may also extend between the sidewall of the conductive pad 120 and the sidewall of the conductive electrode 150, as shown in FIG. 1A. In other embodiments, the spacer layer 140 may not extend as far, may be discontinuous, or may be omitted.

In embodiments of FIG. 1A, a conductive bump 170 may be provided on the conductive electrode 150. This bump 170 may be used to connect with another integrated circuit in a stacked structure. In other embodiments, as illustrated in FIG. 1B, an integrated circuit structure 100a′ need not include the conductive bump 170 thereon.

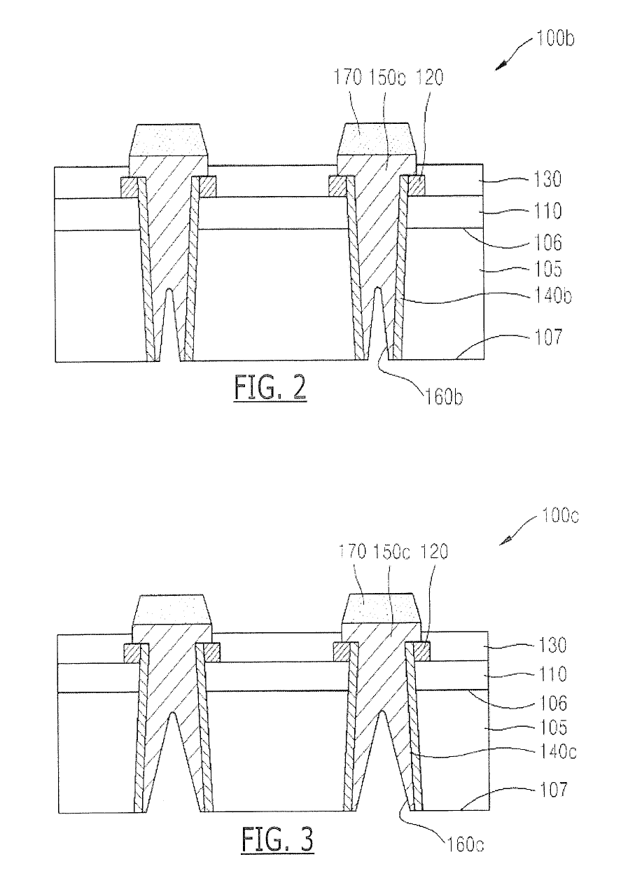

FIG. 2 illustrates a cross-section of an integrated circuit structure 100b according to other embodiments. In these embodiments, the conductive electrode 150b is tapered, as is the through hole, such that the width thereof gradually decreases from the first face 106 to the second face 107. The conductive electrode 150b may extend through and onto the pad 120. The through hole may taper linearly, nonlinearly and/or in an abrupt (stepped) manner. In these embodiments, the height of the void 160b may be smaller than the height of the void 160a of FIGS. 1A and 1B. Moreover, the spacer insulating layer 140b may also extend obliquely through the substrate 105 and the interlayer dielectric layer 110, conformally along the tapered through hole. The spacer layer 140 may not extend as far, may be discontinuous, or may be omitted.

FIG. 3 illustrates a cross-section of an integrated circuit 100c according to other embodiments, wherein the conductive electrode 150c has a reverse tapered shape that gradually increases from the first face 106 to the second face 107. The conductive electrode 150c may extend through and onto the pad 120. The through hole may taper linearly, nonlinearly and/or in an abrupt (stepped) manner. In these embodiments, the height of the void 160c may be larger than the height of the void 160a of FIGS. 1A and 1B. Moreover, the spacer insulating layer 140c may extend obliquely through the substrate 105 and the interlayer dielectric layer 110, conformally along the tapered through hole.

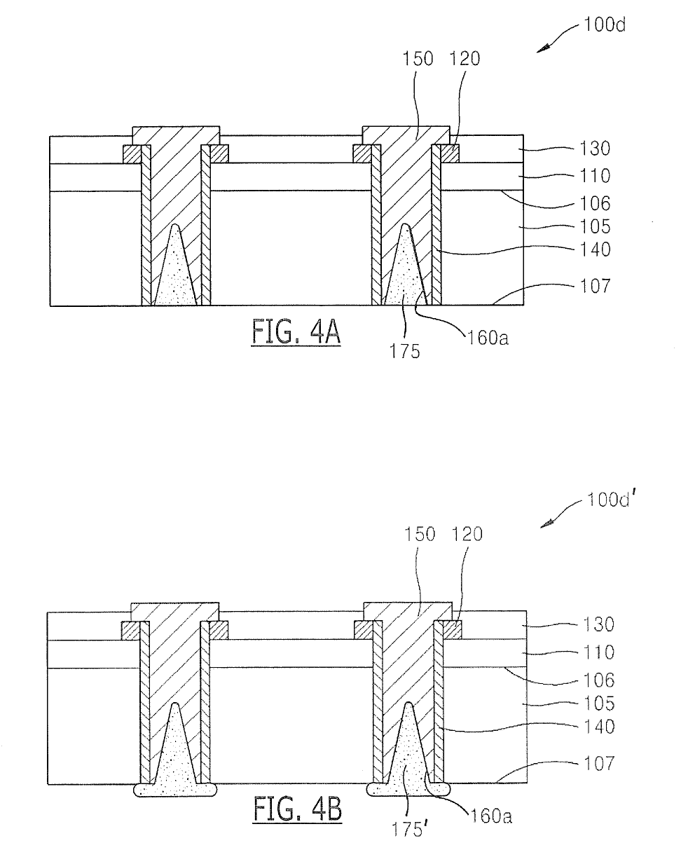

FIGS. 4A and 4B are cross-sectional views of integrated circuit structures 100d, 100d′, according to other embodiments. Compared to FIGS. 1A or 1B, FIGS. 4A and 4B add a conductive material 175 in the void 160a, that directly contacts the inner walls of the conductive electrode 150. The conductive material 175 and the conductive electrode 150 may comprise the same material and/or different material. In embodiments of FIG. 4A, the conductive material 175 is flush with the second face 107. In contrast, in embodiments of FIG. 4B, the conductive material 175′ protrudes outside the void beyond the substrate 105. Embodiments of FIGS. 4A and 4B may be used to enhance the connection reliability between integrated circuits in a stacked structure, as will be described in detail below.

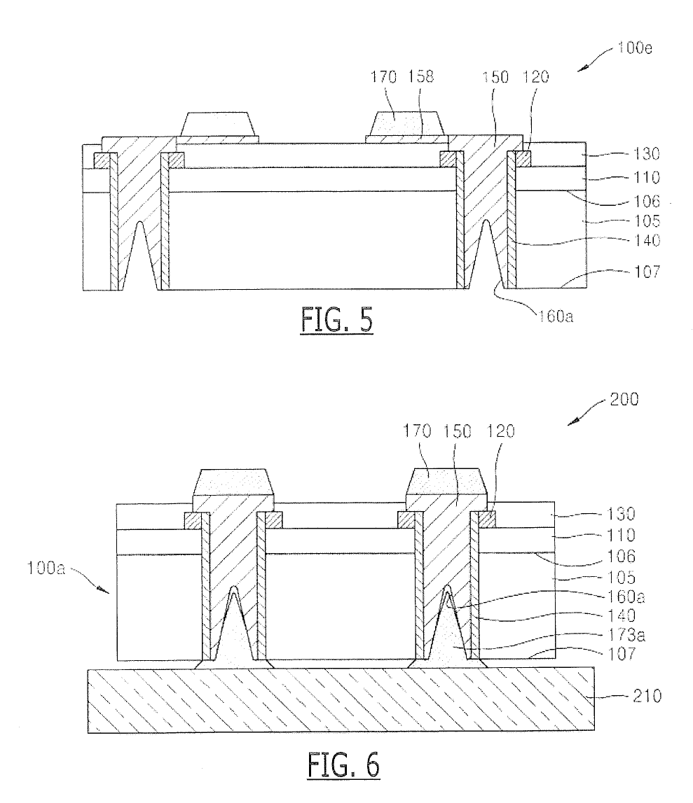

FIG. 5 is a cross-sectional view of an integrated circuit structure 10e according to still other embodiments. In these embodiments, a redistribution line 158 on the passivation layer 130 electrically contacts and extends away from the pad 120, and a conductive bump 170 is provided on the redistribution line 150, offset from the pad 120. More specifically, the conductive electrode 150 is not aligned with the conductive bump 170 relative to the substrate 105, but, rather, is laterally offset. The conductive electrode 150 may be connected to the conductive bump 170 using a redistribution line 158 that may be formed on the passivation layer 130 and that extends away from the conductive electrode 150. The shape and/or position of the redistribution line 158 may vary depending upon the arrangement of the conductive electrode 150 and the conductive bump 170.

FIG. 6 is a cross-sectional view of integrated circuit structures 200 according to other embodiments. In these embodiments, a second substrate 210 is provided on the second face 107. A conductive bump 173a on the second substrate 210 extends into the void 160a and directly contacts the inner walls of the conductive electrode 150. The second substrate 210 may be another integrated circuit structure or other second level packaging substrate, such as a printed circuit board. Moreover, the conductive bump 173a may be fabricated in a conical shape, as illustrated in FIG. 6, and pushed into the void 160a to form a large contact area (joining interface) for attachment compared to absence of the void 160a. In other embodiments, the conductive bump 173a may be of a different shape than the void and may be deformed when pushing the second substrate 210 towards the integrated circuit substrate 105. In still other embodiments, the pushing may take place at an elevated temperature, so as to soften the conductive bump 173a and facilitate deformation. In yet other embodiments, sufficient heating may be performed so as to reflow the conductive bump 173a and cause the bump 173a to conformally form against the walls of the void 160a by capillary action. In this case, a void may be left, having a smaller size than that of the void 160a. In all of these embodiments, an extended contact area (joining interface) may be provided compared to a flat-bottomed conductive electrode 150 that does not include a void 160a therein. It will also be understood that embodiments of FIG. 6 may be combined with any of the other embodiments herein.

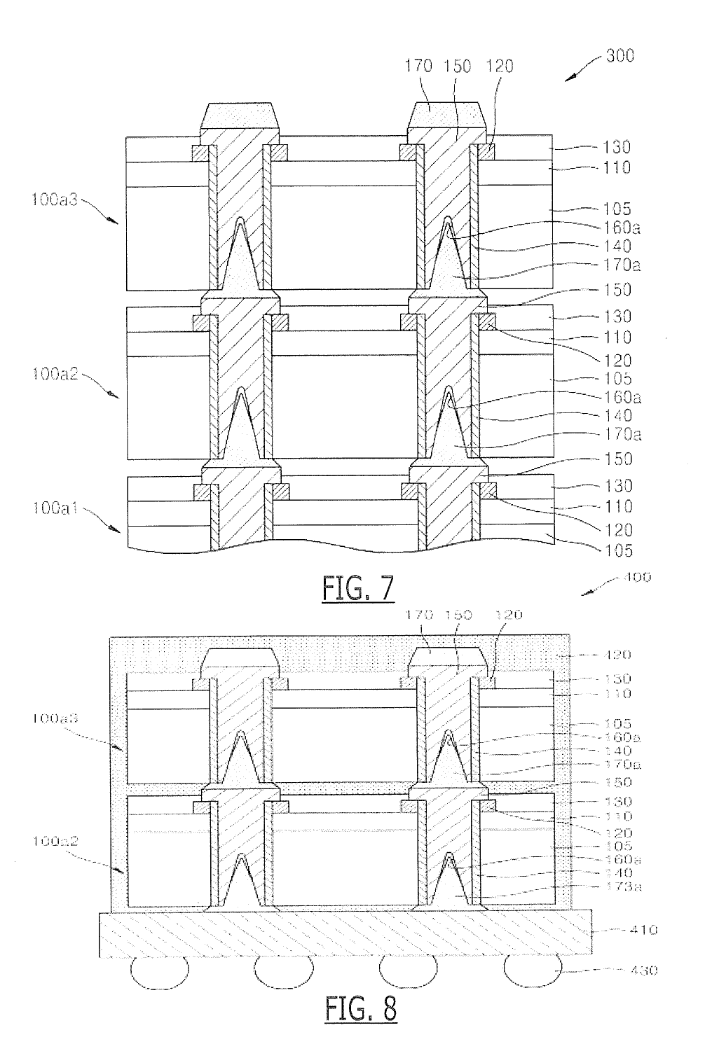

FIG. 7 illustrates a stacked integrated circuit structure 300 according to other embodiments. In these embodiments, the integrated circuit substrate is a first integrated circuit substrate 100a3 and a second integrated circuit substrate 100a2 is provided that itself includes a pad 120, a through hole, a conductive electrode 150 and a second void 160a having a void opening adjacent the second face 107 of FIG. 4B that defines second inner walls of the second conductive electrode. As shown, a second conductive bump 170a extends from the second conductive electrode adjacent the second pad 120 into the first void and directly contacts the inner walls of the first conductive electrode 150. Moreover, a third substrate 100a1 also may be provided that may itself be a third integrated circuit substrate 105 or a second level packaging substrate, and may be connected to the second substrate 100a2 via another set of conductive bumps 170a.

Accordingly, FIG. 7 illustrates embodiments wherein at least two integrated circuit substrates 100a1, 100a2, 100a3 . . . , are stacked in a three-dimensional stack using conductive bumps according to any of the embodiments described herein. The conductive bump 170 of the topmost substrate 100a3 may need not be provided. Moreover, the integrated circuit substrates may be provided according to any of the embodiments of the present invention. More than three substrates also may be stacked.

FIG. 8 is a cross-sectional view of other embodiments. In these stacked package structures 400, at least two integrated circuit substrates 100a2, 100a3 are stacked on a second level packaging substrate 410, such as a printed circuit board, and include a circuit interconnection therebetween, using conductive circuit bumps 170a, 173a. It will be understood that the conductive bumps 170 of the topmost substrate 100a3 may be omitted. Moreover, a plurality of third conductive bumps, such as solder bumps 430 are attached to the other side of the packaging substrate 410, so as to connect the third conductive bumps 430 to the integrated circuit substrates 100a2, 100a3 through the circuit interconnections, the second conductive bumps 173a and the conductive bumps 170a. A molding layer 420 also may be provided that extends from the third substrate 410 and that covers the first and second integrated circuit substrates 100a2, 100a3. The molding layer may comprise resin and/or other encapsulation material. A molding layer also may be used with any of the other embodiments described herein. In this case, a void may be left, having a smaller size than that of the void 160a.

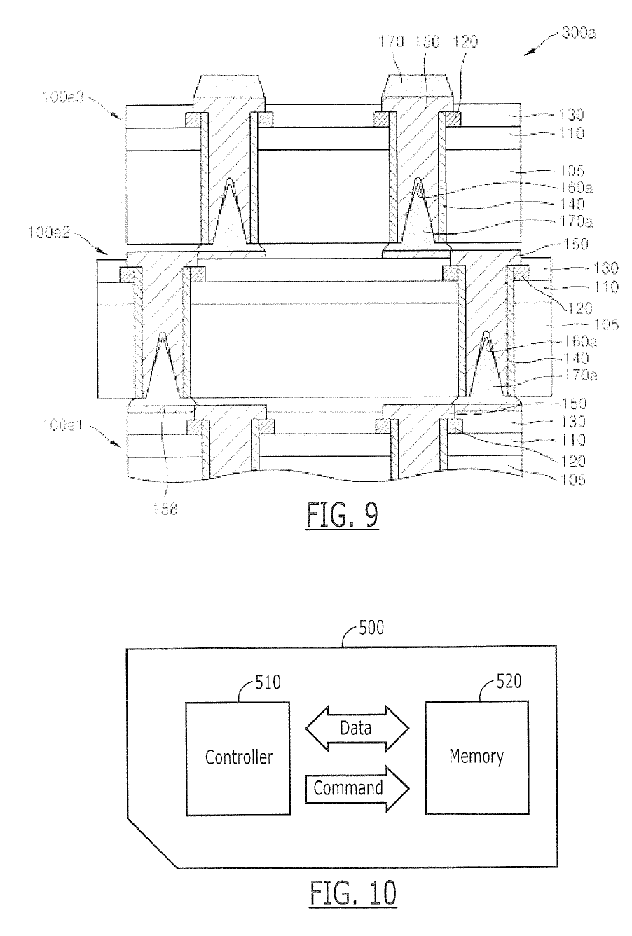

FIG. 9 is a cross-sectional view of other embodiments of the present invention. In particular, the stack structure 300a of FIG. 9 uses via electrodes among integrated circuits 100e1, 100e2, 100e3 that are not vertically aligned, but use redistribution lines 158 to align the conductive bumps 170a to the voids 160a. The integrated circuit substrates may be the same as one another and/or different from one another, and may be of the same size and/or of different size from one another. The conductive bumps 170 of the topmost integrated circuit 100e3 may be omitted. In this case, a void may be left, having a smaller size than that of the void 160a.

FIG. 10 is a block diagram of a card 500 that includes a controller 510 and a memory integrated circuit 520 that exchanges data with the controller 510 in response to commands from the controller 510. The card 500 may be used to store data in the memory 520 or to output data from the memory 520 to external of the card 500. The memory 520 may comprise at least one integrated circuit structure (single or stacked), according to any of the embodiments described herein. The card 500 may be used as a Multi Media Card (MMC), a Secure Digital (SD) card or any other conventional card that is used in, for example, portable electronic devices.

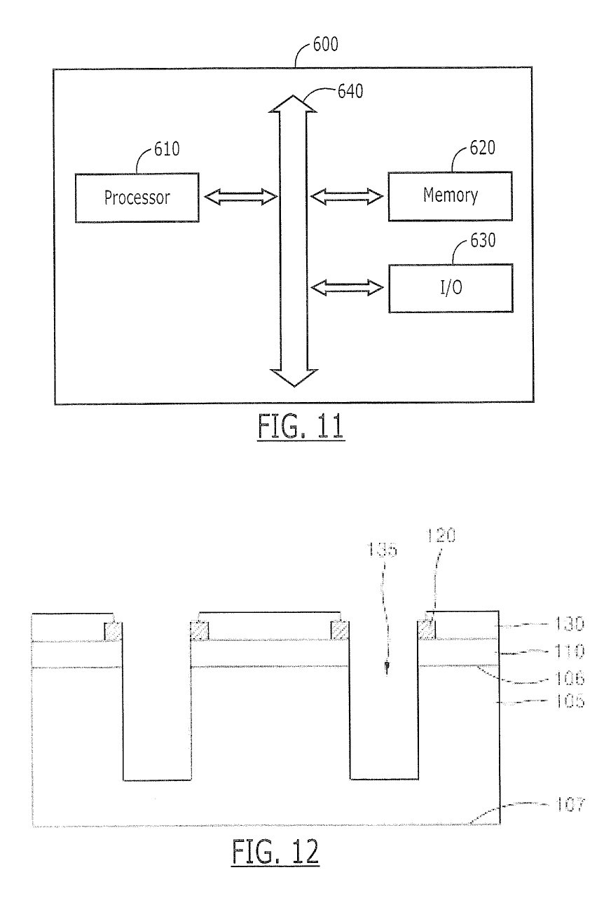

FIG. 11 is a block diagram of an electronic system according to various embodiments of the present invention. The electronic system 600 may include a processor 610, one or more input/output (I/O) devices 630, such as a touch screen, and a memory 620 that communicate to one another through a bus 640. The processor 610 may operate on stored programs and control the system 600. The I/O element 630 may be used to input/output data and provide a user interface. The system 600 may be connected to another device, such as a personal computer, a network, etc., using the I/O element 630 to thereby exchange the data with the other device. The memory 620 stores the programming and/or data for operating the processor 600. The memory 620 and/or the processor 610 may comprise at least one integrated circuit (a single integrated circuit or a stacked structure) according to any of the embodiments described herein. The system 600 may be configured to provide a mobile phone, digital media player, a navigation system, a solid state disk, a household appliance and/or any other electronic system.

FIGS. 12-25 are cross-sectional views illustrating methods of fabricating integrated circuit structures according to various embodiments, and integrated circuit structures so formed according to various embodiments. In general, these methods include forming a through hole in an integrated circuit substrate having a conductive pad on a first face thereof, the through hole extending through the integrated circuit substrate from a second face of the integrated circuit substrate that is opposite the first face to the first face and through the pad. A conductive electrode is formed in the through hole that extends from the second face to the first face and through and onto the pad, and that includes a void therein adjacent the second face, the void including a void opening adjacent the second face and defining inner walls of the conductive electrode.

Moreover, in some embodiments, a conductive bump is formed on the conductive electrode adjacent the pad. Moreover, in other embodiments, a conductive material is pushed into the void to directly contact the inner walls of the conductive electrode. The conductive material may also protrude outside the void beyond the substrate. Pushing may be performed at elevated temperature, so as to increase plasticity of the conductive material as it is pushed into the void. In other embodiments, the conductive material is reflowed into the void to directly contact the inner walls of the conductive electrode. In still other embodiments, a redistribution line may be formed on the passivation layer that electrically contacts and extends away from the pad, and the conductive bump may be formed on the redistribution line, offset from the pad. In other embodiments, a conductive bump on a second substrate may be pushed into the void to directly contact the inner walls of the conductive electrode. Pushing may be performed at room temperature and/or an elevated temperature. In other embodiments, reflowing may be performed. The conductive bump may be on a packaging substrate or on a second integrated circuit substrate. A molding layer may also be provided for encapsulation.

Other method embodiments will now be described in connection with FIGS. 12-16, which illustrate the formation of integrated circuit structures 100a of FIG. 1A. Analogous methods may be used to fabricate integrated circuit structures of the other embodiments described herein.

Referring to FIG. 12, an insulating layer 110 including a plurality of integrated circuit layers therein is formed on a first face 106 of an integrated circuit substrate 105. The insulating layer 110 may be planarized using chemical-mechanical polishing (CMP) and/or etch-back processes. A conductive pad 120 is formed on the insulating layer 110. A passivation layer 130, such as an oxide layer and/or a nitride layer, is formed on the insulating layer 110, partially exposing the conductive pad 120. A blind hole 135 is then formed through the conductive pad 120, through the insulating layer 110 and partially through the integrated circuit substrate 105, so as to extend from the first face 106 thereof partially to the second face 107 thereof.

The blind hole 135 may be formed using laser drilling, dry etching and/or other techniques. The blind hole 135 only extends to a predetermined depth of the substrate 105. In some embodiments, dry etching may be performed in combination with a photolithography process. However, in other embodiments, laser drilling may be performed without the need to provide a photolithography process. The blind hole 135 may have a variety of shapes depending upon the etching and/or drilling conditions. For example, the blind hole 135 may have a cylindrical shape having a uniform diameter, a tapered shape that narrows in the downward direction and/or a reverse tapered shape that widens in the downward direction. In other embodiments, the blind hole 135 may be ellipsoidal and/or polygonal in cross-section. It will also be understood that the blind hole 135 may be formed prior to forming the insulating layer 110, the pad 120 and/or the passivation layer 130.

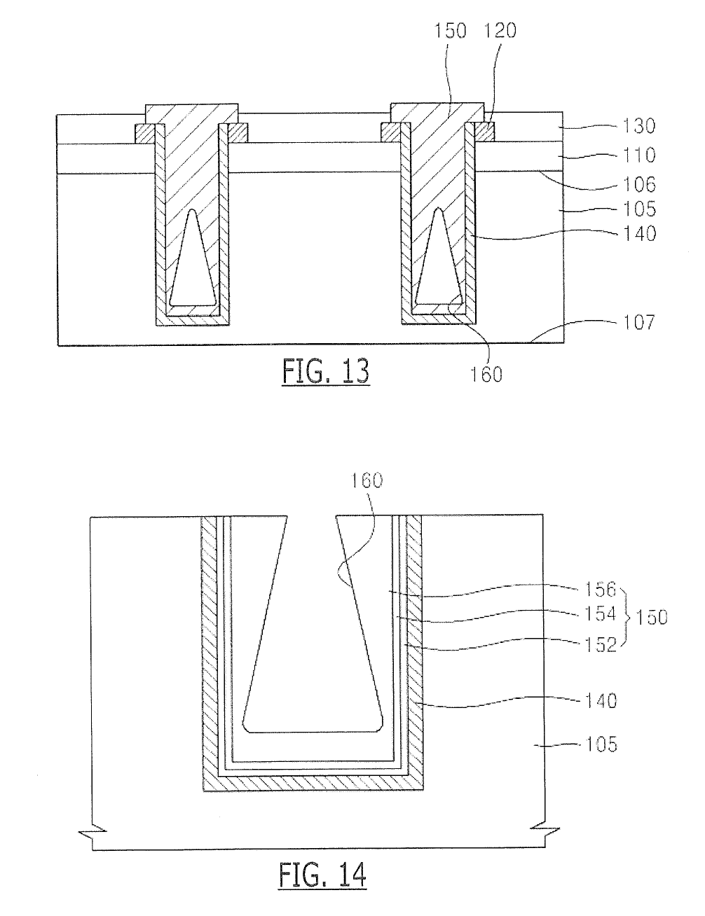

Then, referring to FIG. 13, a conductive electrode 150 is formed in the blind hole 135, such that the conductive electrode 150 fills the blind hole 135 adjacent the first face 106 and produces a void 160 therein adjacent the second face 107. More specifically, referring to FIG. 13, a spacer insulating layer 140 may be formed in the blind hole 135. The spacer material, such as oxide, nitride, polymer and/or parylene is formed on the surfaces of the blind hole using, for example, low temperature CVD, polymer spraying, low temperature physical vapor deposition, etc. Then, a portion of the material formed on the conductive pad 120 and/or the passivation layer 130 may be selectively removed, leaving the material in the blind hole 135. In some embodiments, when removing material on the pad 120 using an anisotropic etch method, a portion of the material on the bottom surface of the blind hole 135 may also be removed so that, in some embodiments, the spacer insulating layer 140 may remain only on the sidewalls. In other embodiments, a portion of the material on the exposed sidewalls of the conductive pad 120 may be removed.

A conductive electrode 150 is then formed on the spacer insulating layer 140. The conductive electrode 150 may be formed by chemical vapor deposition, so as to form a void 160 therein. In other embodiments, as shown in FIG. 14, the conductive electrode 150 may be formed by electroplating. In these embodiments, the conductive electrode 150 may comprise a barrier metal 152, a seed metal 154 and an interconnection metal 156. The barrier metal 152 may comprise titanium (Ti), tantalum (Ta) and/or tantalum nitride (TaN), and the seed metal 154 and the interconnection metal 156 may comprise copper (Cu). Again, a void 160 is formed by the electroplating process. For example, in an electroplating method, when the diameter of the conductive electrode 150 is between about 35 μm and about 75 μm, a void may be generated above about 2.5 mA/cm² current density when electroplating using DC current. Other plating methods, such as pulse current mode or pulse reverse mode also may be used. Finally, in forming the conductive electrode using a deposition method, the interconnection metal 156 may be directly formed on the barrier metal layer 152 without the need for a seed metal 154. In these embodiments, the conductive electrode 150 may comprise aluminum and/or tungsten.

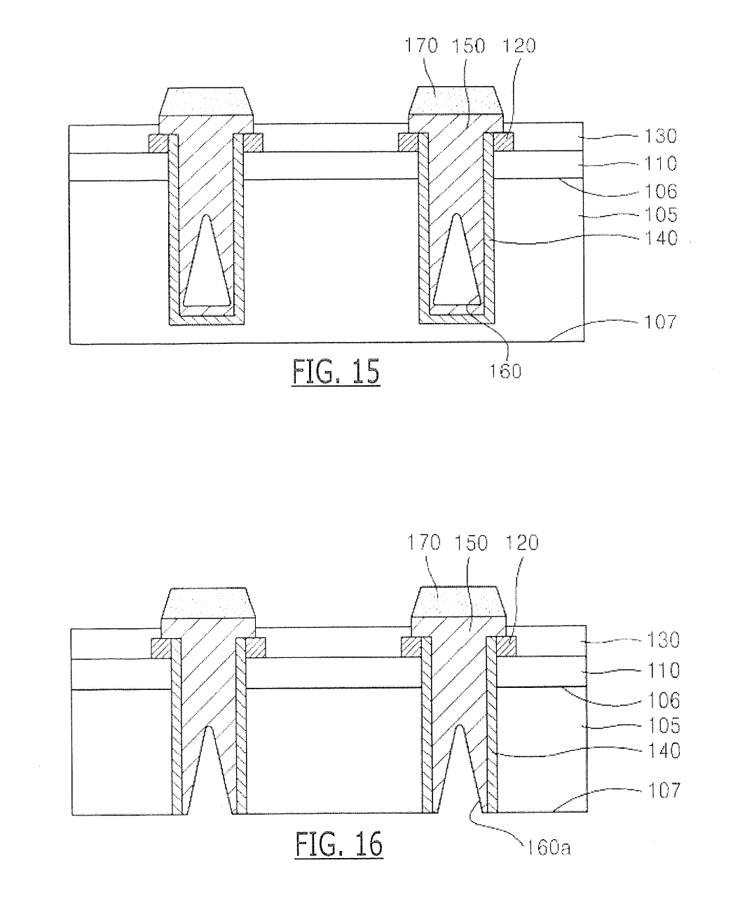

Referring now to FIG. 15, if desired, a conductive bump 170 may be formed on the top surface of the via electrode 150. For example, when the interconnection metal 156 of FIG. 14 is copper, the conductive bump 170 may comprise a tin-based alloy that has a good wetting characteristic on the copper. In other embodiments, a lead-free tin alloy may be employed. The size or volume of the conductive bump 170 may vary in proportion to the size of the void 160, in some embodiments.

Then, referring to FIG. 16, at least some of the substrate 105 is removed from the second face 107 thereof to expose the void 160. Specifically, as shown in FIG. 16, a portion of the substrate 105 including portions of the spacer insulating layer 140 and the conductive electrode 150 is removed to a predetermined thickness from the second surface 107 using chemical-mechanical polishing, isotropic etching, wet etching and/or anisotropic etching, to expose the via electrode 150 and the void 160a. For example, in some embodiments, when at least 10% of the via electrode 150 is removed, the void 160a may be exposed at the second surface 107. Moreover, as the size of the via electrode decreases, this removal ratio may be further decreased.

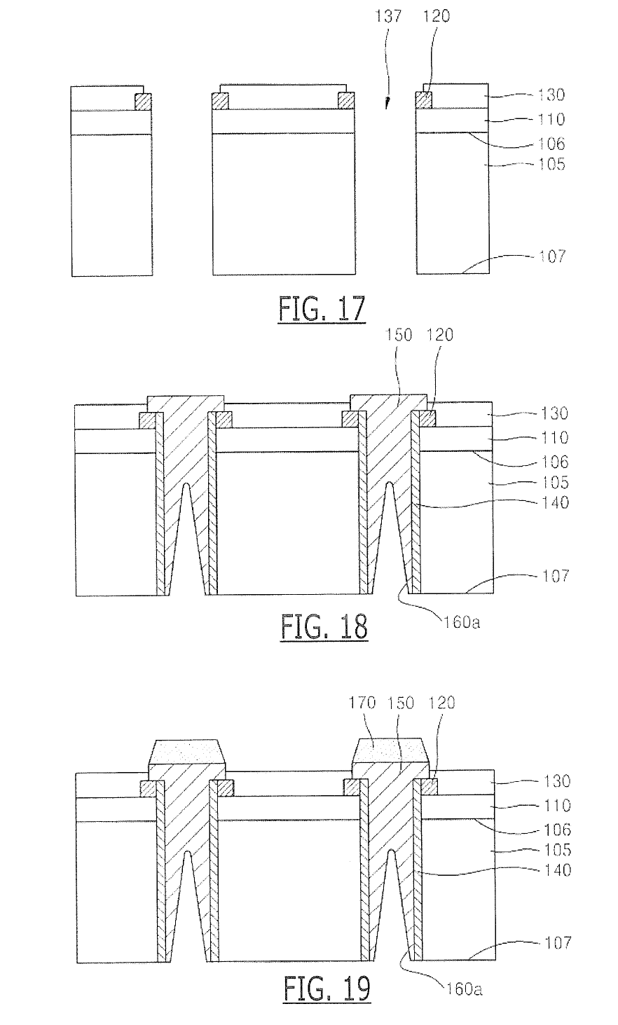

FIGS. 17-19 illustrate alternative methods of fabricating an integrated circuit structure according to other embodiments. In general, in these embodiments, a through hole is first formed and then a conductive electrode including the void is formed in the through hole.

More specifically, referring to FIG. 17, a through hole 137 is formed through the conductive pad 120, the insulating layer 110 and the substrate 105. Then, referring to FIG. 18, the spacer insulating layer 140 is formed in the through hole 137. Conductive electrode 150 is formed on the spacer insulating layer 140. Since the aspect ratio of through hole 137 may be high compared to the blind hole 135 of FIG. 12, the height of the void 160a may be higher than in the case of FIG. 12. Due to the high aspect ratio of the through hole 137, the conductive electrode 150 forms with the void 160a therein. Finally, referring to FIG. 19, a conductive bump 170 may be formed on the conductive electrode 150.

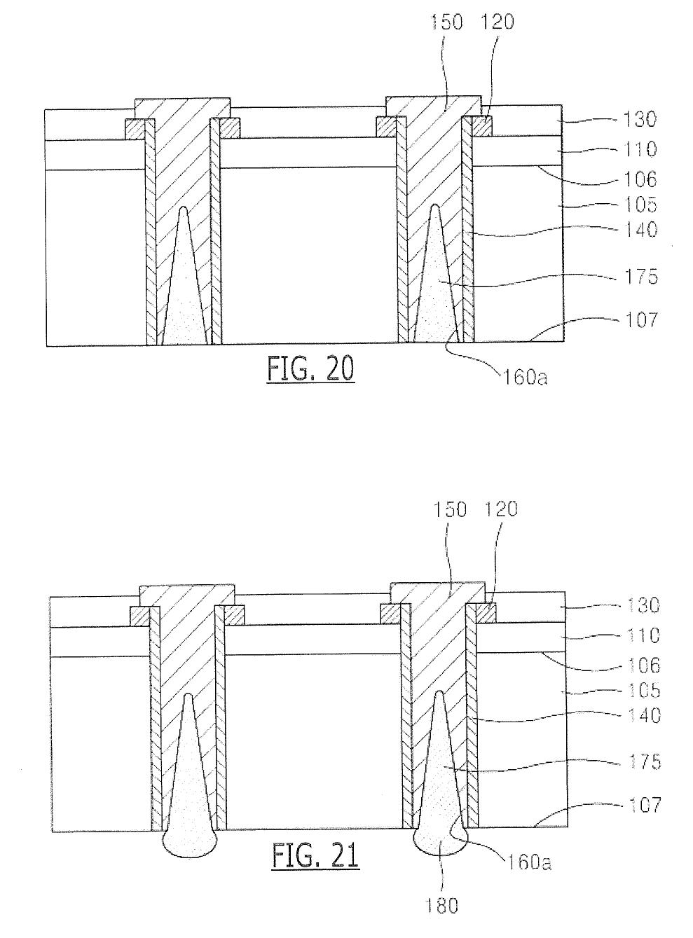

FIG. 20 illustrates other embodiments of the invention which may be performed following embodiments of FIGS. 16, 18 or 19. In embodiments of FIG. 20, the conductive filler 175 is filled in the void 160a. The conductive filler 175 may be the same material as the conductive electrode 150 or the conductive bump 170 and/or may be a different material.

FIG. 21 illustrates yet other embodiments of FIG. 20, wherein the conductive filler 180 may protrude from the second surface 107 to facilitate connection with another conductive electrode when stacking the integrated circuits.

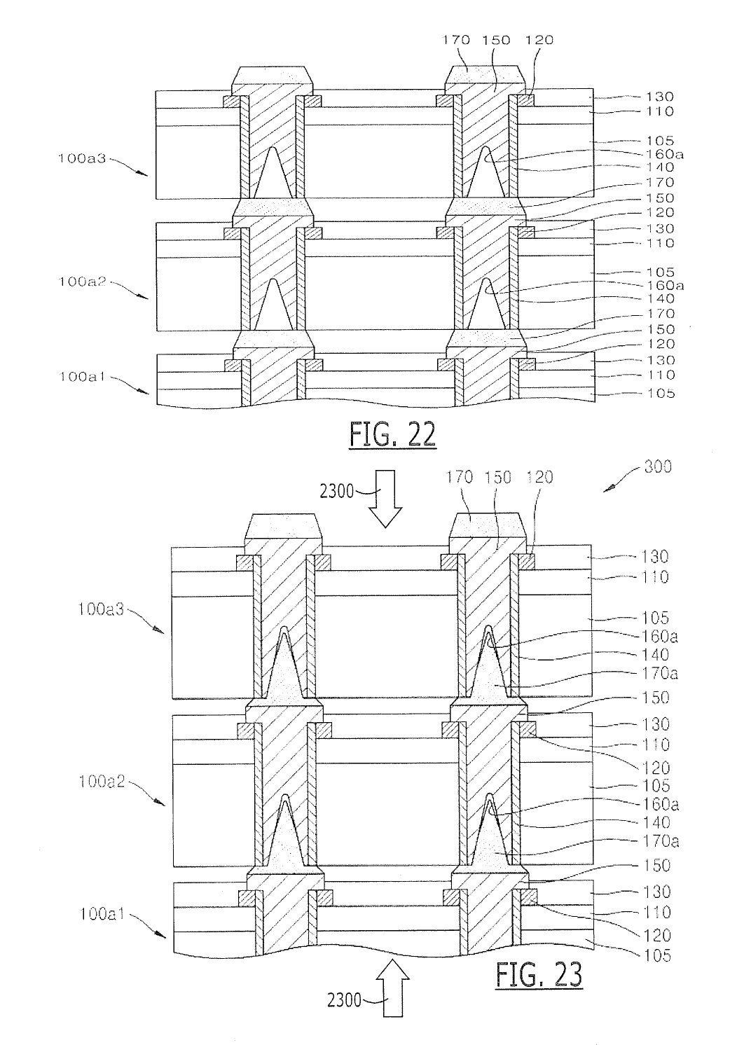

FIGS. 22 and 23 illustrate methods according to other embodiments that may be used to fabricate embodiments of FIG. 7. Referring now to FIG. 22, a plurality of integrated circuit structures 100a1-100a3 that include conductive electrodes 150 and conductive pads 170 thereon are stacked, as shown in FIG. 22. Then, as shown in FIG. 23, the conductive pads 170 are pushed into the voids 160a to directly contact the inner walls of the conductive electrodes 150. The integrated circuit structures 100a1, 100a2 and 100a3 may be pushed against one another, as shown by opposing arrows 2300 in FIG. 23. Pushing from only one end (one of the arrows 2300) also may be provided in other embodiments.

In some embodiments of FIG. 23, the conductive bumps 170a are plastically deformed by compressing the substrates 100a1, 100a2, 100a3 toward one another as shown by arrow(s) 2300. In these embodiments, the conductive bumps 170 may comprise lead free, tin-based alloys that have a good plasticity characteristic and are soft. Accordingly, the conductive bumps 170 of FIG. 22 plastically deform to conform to the inner walls in the voids 160a of the conductive electrodes 150.

In other embodiments, the pushing of FIG. 23 takes place at an elevated temperature, so as to increase the plasticity of the conductive material during the pushing into the void 160a. In some embodiments, heating may take place below the melting point of the conductive material 170, so as to soften the conductive material while pushing. In other embodiments, heating actually takes place above the reflow temperature of the conductive material 170, so that the conductive material actually reflows onto the inner wall in the void 160a of the conductive electrode 150. Thus, for example, when a tin-based alloy is used, heating may be performed at a temperature above about 250° C., so as to cause the tin-based material to wet onto the surface of the conductive electrode 150 and at least partially fill the void 160a by melting. In these embodiments, little or reduced compression (arrow(s) 2300) may be needed, because the conductive material 170 actually melts. Embodiments of FIGS. 22 and 23 may also be performed using offset bumps of FIG. 9 and/or any of the other embodiments described herein.

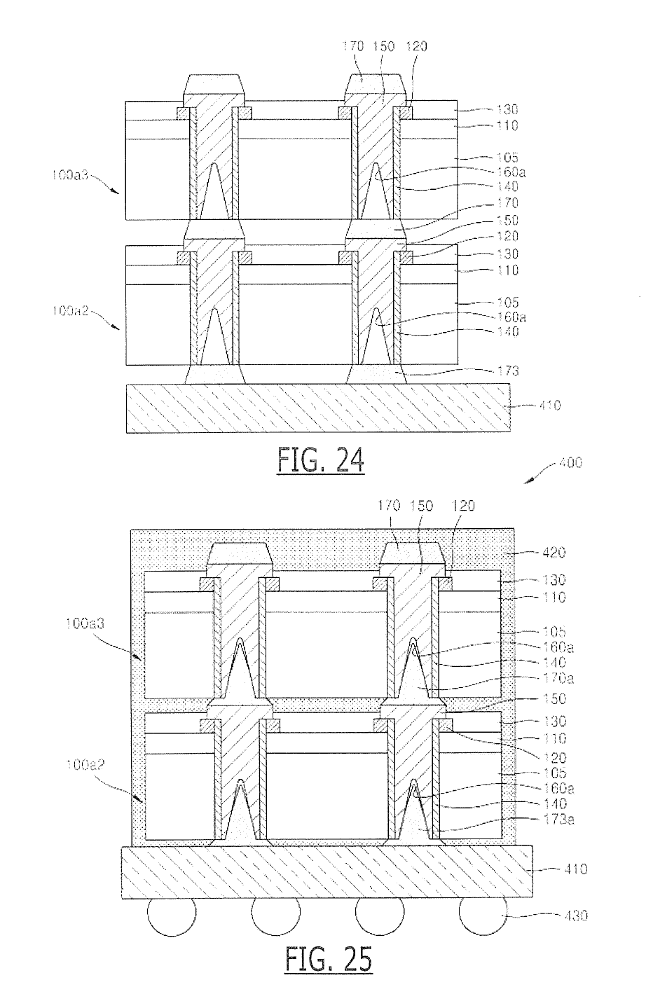

FIGS. 24 and 25 illustrate methods of forming integrated circuit structures of FIG. 8. As shown in FIG. 24, a plurality of structures 100a2, 100a3, 410 are stacked, as was described, for example, in connection with FIGS. 22 and 23. However, the bottommost element of the stack may be a second level packaging substrate 410 that uses second conductive bumps 173. The conductive bumps and the voids may be aligned as shown. Then, any of the methods that are described in connection with FIGS. 22 and 23 may be used to connect the integrated circuit substrates 100a2, 100a3 and the mounting substrate 410 using compression and/or thermal processes, as was described above in connection with FIG. 23. A molding layer 420 may then be formed on the substrate 410 covering the integrated circuit structures 100a3 and 100a2, as shown in FIG. 25. Third conductive bumps 430 may then be attached to the bottom surface of the substrate 410.

Accordingly, various embodiments of the present invention can use a void, which was heretofore regarded as being undesirably formed in a through silicon via, as a joining interface that can increase the reliability of packaged substrates. Fabrication methods according to various embodiments may be used to form the void in the through silicon via, and may use the voids so formed to provide an enhanced joining interface.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

In the drawings and specification, there have been disclosed embodiments of the invention and, although specific terms are employed, they are used in a generic and descriptive sense only and not for purposes of limitation, the scope of the invention being set forth in the following claims.

1. An integrated circuit structure comprising:
an integrated circuit substrate having a conductive pad on a first face thereof and a through hole that extends through the integrated circuit substrate and the pad; and
a conductive electrode in the through hole and through and onto the pad, and including a void therein adjacent a second face of the integrated circuit substrate, the void including a void opening adjacent the second face that defines inner walls of the conductive electrode.

2. An integrated circuit structure according to claim 1 wherein the void is a tapered void that tapers from the void opening and wherein the inner walls are tapered inner walls.

3. An integrated circuit structure according to claim 2 wherein the tapered void also defines a void width that decreases from the second face toward the first face.

4. An integrated circuit structure according to claim 1 wherein the through hole is a tapered through hole.

5. An integrated circuit structure according to claim 1 further comprising a conductive bump on the conductive electrode adjacent the pad.

6. An integrated circuit structure according to claim 1 further comprising a conductive material in the void that directly contacts the inner walls of the conductive electrode.

7. An integrated circuit structure according to claim 6 wherein the conductive material also protrudes outside the void, beyond the substrate.

8. An integrated circuit structure according to claim 1 further comprising:
a redistribution line on the first face that electrically contacts and extends away from the pad; and
a conductive bump on the redistribution line, offset from the pad.

9. An integrated circuit structure according to claim 1 further comprising:
a second substrate on the second face; and
a conductive bump on the second substrate that extends into the void and directly contacts the inner walls of the conductive electrode.

10. An integrated circuit structure according to claim 9 wherein the integrated circuit substrate is a first integrated circuit substrate, the pad is a first pad, the through hole is a first through hole, the conductive electrode is a first conductive electrode, the void is a first void, the inner walls are first inner walls and wherein the second substrate comprises:
a second integrated circuit substrate having a second conductive pad on a first face thereof and a second through hole that extends through the second integrated circuit substrate from a second face of the second integrated circuit substrate that is opposite the first face to the first face and through the second pad; and
a second conductive electrode in the second through hole that extends from the second face to the first face of the second integrated circuit substrate and through and onto the second pad, and that includes a second void therein adjacent the second face, the second void having a void opening adjacent the second face that defines second inner walls of the second conductive electrode;
wherein the conductive bump extends from the second conductive electrode adjacent the second pad into the first void and directly contacts the first inner walls of the first conductive electrode.

11. An integrated circuit structure according to claim 10 wherein the conductive bump is a first conductive bump, the integrated circuit further comprising:
a third substrate on the second face of the second integrated circuit substrate; and
a second conductive bump on the third substrate that extends into the second void and directly contacts the second inner walls of the second conductive electrode.

12. An integrated circuit structure according to claim 9 further comprising:
a molding layer that extends from the second substrate and that covers the integrated circuit substrate.

13. An integrated circuit structure according to claim 11 further comprising:
a molding layer that extends from the third substrate and that covers the first and second integrated circuit substrates.

14. An integrated circuit structure according to claim 1 wherein the integrated circuit substrate is a first integrated circuit substrate, the pad is a first pad, the through hole is a first through hole, the conductive electrode is a first conductive electrode, the void is a first void, and the inner walls are first inner walls, the integrated circuit structure further comprising:
a second integrated circuit substrate having a second conductive pad on a first face thereof and a second through hole that extends through the second integrated circuit substrate from a second face of the second integrated circuit substrate that is opposite the first face to the first face and through the second pad;
a second conductive electrode in the second through hole that extends from the second face to the first face of the second integrated circuit substrate and through and onto the second pad, and that includes a second void therein adjacent the second face, the second void having a void opening adjacent the second face that defines second inner walls of the second conductive electrode; and
a conductive bump that extends from the second conductive electrode adjacent the second pad to directly contact the first conductive electrode outside the first void.

15. An integrated circuit structure according to claim 1 wherein the integrated circuit substrate comprises an integrated circuit memory device substrate, the integrated circuit structure further comprising a processor and an input/output system that are connected to the integrated circuit memory device substrate via the conductive electrode to provide an electronic system.

16. An integrated circuit structure according to claim 1 wherein the through hole extends through the integrated circuit substrate from the second face of the integrated circuit substrate that is opposite to the first face.

17. An integrated circuit structure according to claim 1 wherein the integrated circuit substrate comprises an integrated circuit memory device substrate, the integrated circuit structure further comprising a memory controller that is connected to the integrated circuit memory device substrate via the conductive electrode to provide a memory card.

18. A method of fabricating an integrated circuit structure comprising:
forming a through hole in an integrated circuit substrate having a conductive pad on a first face thereof, the through hole extending through the integrated circuit substrate and the pad; and
forming a conductive electrode in the through hole and through and onto the pad, and including a void therein adjacent a second face of the integrated circuit substrate, the void including a void opening adjacent the second face that defines inner walls of the conductive electrode.

19.-32. (canceled)

33. A method of fabricating an integrated circuit structure comprising:
forming a blind hole in an integrated circuit substrate that extends only partially through the integrated circuit substrate from a first face thereof partially to a second face thereof;
forming a conductive electrode in the blind hole such that the conductive electrode fills the blind hole adjacent the first face and produces a void therein adjacent the second face; and
removing at least some of the substrate from the second face to expose the void.

34. (canceled)

35. A method according to claim 33 further comprising:
pushing a conductive material into the void to directly contact the conductive electrode in the void.

36.-47. (canceled)
